(19) United States
(12) Patent Application Publication
(10) Pub. No.: US 2025/0341581 A1
(43) Pub. Date: Nov. 6, 2025

(54) PROCESSOR IMPLEMENTED METHOD FOR PREDICTING AGING EFFECTS IN A BATTERY

(71) Applicant: The Hong Kong University of Science and Technology, Hong Kong (CN)

(72) Inventors: Xijun HU, Hong Kong (CN); Leung Yuk Frank LAM, Hong Kong (CN); Chi Ho WONG, Hong Kong (CN)

(21) Appl. No.: 19/196,814

(22) Filed: May 2, 2025

Related U.S. Application Data
(60) Provisional application No. 63/641,944, filed on May 2, 2024.

(51) Int. Cl. G01R 31/367; G01R 31/3835; G01R 31/392

(52) U.S. Cl. CPC G01R 31/367; G01R 31/3835; G01R 31/392

(57) ABSTRACT

A processor implemented method of predicting the aging effects in a battery, the method comprises capturing data of voltage and time of the battery; inputting the data of voltage and time curve into a trained LSTM network; and outputting the predicted data of voltage and time curve; wherein the trained LSTM network is configured to be trained by the following steps: selecting the input data sample; defining the initial hidden state, the initial cell state, bias, weight, current weight; setting an epoch, an initial learning rate, a gradient threshold, and a drop factor; and training the LSTM network as per the set parameters.

### CROSS-REFERENCE TO RELATED APPLICATIONS

This application claims priority to, and the benefit of, U.S. Provisional Patent Application Ser. No. 63/641,944 filed May 2, 2024, the disclosure of which is incorporated by reference herein in its entirety.

### TECHNICAL FIELD

The present application relates to a processor implemented method of predicting the aging effects in a battery and a lithium-sulfur battery.

### BACKGROUND

Lithium-sulfur (Li—S) batteries are known for their exceptional theoretical energy density and are considered promising candidates for next-generation energy storage systems. Despite these advantages, their commercialization is significantly hindered by the polysulfide shuttle phenomenon, which is a major challenge in achieving their full theoretical potential. This phenomenon occurs during the discharge cycle when soluble polysulfide ions migrate from the cathode to the anode, depleting the active sulfur mass and forming deleterious layers on the anode, thereby reducing the battery's overall performance. Researchers have sought to address these challenges through various strategies, primarily focusing on the use of metal oxides and other adsorptive materials at the cathode to capture migrating polysulfides. Commonly employed materials include SnO₂, MnO₂, Al₂O₃, Fe₂O₃, and TiO₂, which engage in Lewis acid interactions to adsorb polysulfides. Despite their benefits, the inherent insulating properties of some of these materials, such as TiO₂, necessitate additional conductive agents or complex structural designs to enhance their electrical conductivity, thus increasing production costs and complicating the manufacturing process. Further, titanium compounds have been explored for their environmental and safety advantages.

The synthesis of titanium nitride (TiN), although noted for its catalytic influence on polysulfide conversion and exceptional polarization effect, often involves complex, high-temperature processes or the use of hazardous chemicals, limiting its practical application on a large scale. In prior studies, TiO₂—TiN composites were typically synthesized by an oxidation process of TiN under harsh conditions, such as at high-temperature. However, existing oxidation processes cannot effectively control the oxidation degree, resulting in inconsistent structures among the particles of the TiO₂—TiN composite, for example, some particles were fully oxidized to TiO₂, while others remained largely unreacted. The inconsistent structures lead to phase separation or irregular interfaces between the TiO₂ phase and the TiN phase in the TiO₂—TiN composite and compromise the stability and effectiveness of the composite in Li—S battery applications.

There is a consistent need for a method that can synthesize cathode materials for Li—S batteries in a simpler, more cost-effective, and environmentally friendly manner, while also enhancing the safety and efficiency of these batteries. It also underscores the necessity for quicker and more reliable testing methods to accelerate the development and commercialization of batteries and in particular Li—S batteries.

Currently, battery performance evaluation through cyclic charge-discharge tests is time-consuming. For example, completing sufficient cycles can take weeks or months, especially at lower C-rates, and extended testing duration decreases evaluation efficiency. Further the kink structures in voltage profile during discharge of Li—S batteries is difficult to be predicted.

There thus exists a need for improved methods for predicting aging effects in batteries.

### SUMMARY

To overcome the shortcomings of existing technology, the present disclosure provides a processor implemented method of predicting the aging effects in a battery, such as a TiO₂—TiN/S with a Super P® coated separator.

The present disclosure provides a processor implemented method of predicting the aging effects in a battery, the method comprising:
1) capturing data of voltage and time of the battery;
2) inputting the data of voltage and time curve into a trained long short-term memory (LSTM) network;
3) outputting the predicted data of voltage and time curve;
wherein the trained LSTM network is configured to be trained by the following steps:
   selecting an input data sample;
   defining an initial hidden state, an initial cell state, bias, weight, current weight;
   setting an epoch, an initial learning rate, a gradient threshold, and a drop factor; and
   training the LSTM network as per the set parameters.

In certain embodiments, the loss function for training LSTM is a root-mean-square error (RMSE).

In certain embodiments, the number of epochs is set to be equal to or less than 500, the gradient threshold is set to be equal to 0.1, and the initial learning rate is specified as 0.003.

In certain embodiments, the drop factor is set to be equal to 0.2 or 0.62.

In certain embodiments, the number of epochs is set to be equal to 200 with RMSE=0.005.

The present disclosure further provides a system for predicting the aging effects in a battery, comprising a memory, a processor, and computer program instructions stored in the memory and capable of being run by the processor, and when the computer program is runed by the processor, the method described above can be implemented.

The present application provides the enhancements in Li—S battery technologies and the advanced predictive technologies to optimize battery testing processes, the synthesis and application of novel materials improve the operational efficiency, safety, and environmental impact of Li—S batteries. The present application overcomes significant obstacles inherent to traditional Li—S battery designs, such as the polysulfide shuttle phenomenon, which undermines the battery's energy efficiency and longevity. The present application makes Li—S batteries more practical and efficient for widespread commercial use, enhancing their viability as a next-generation energy storage solution.

### BRIEF DESCRIPTION OF THE DRAWINGS

Exemplary embodiments of the disclosure are described in the following with respect to the attached figures. The figures and corresponding detailed description serve merely to provide a better understanding of the disclosure and do not constitute a limitation whatsoever of the scope of the disclosure as defined in the claims. In particular:

FIG. 1 shows (a) the SEM image, (b) the TEM image, (c), (e) and (f) EDX mapping of the TiO₂—TiN composite prepared in Example 1.

FIG. 2 depicts (a) an adsorption-desorption isotherm obtained by Brunner-Emmet-Teller (BET) analysis, (b) a plot of Barrett-Joyner-Halenda (BJH) Pore distribution analysis and (c) Mercury Porosimetry (MP) plot of the TiO₂—TiN composite prepared in Example 1.

FIG. 3 shows the (a-c) XPS spectrums of TiO₂—TiN composite prepared in Example 1.

FIG. 4 shows cycling performances of TiO₂—TiN/S battery at 0.5C produced in Example 4.

FIG. 5 illustrates LSTM network structure according to certain embodiments of the present disclosure.

FIG. 6 (a-b) shows the diagram of the comparison between the predicted and experimental charge and discharge curves, in which (a) shows the comparison for the 150th cycle, and (b) shows the comparison for the 200th cycle.

FIG. 7 (a-c) show the diagram of the LSTM results with the selected training parameters for the 200th cycle.

FIG. 8 illustrates the flowchart of the processor implemented method of predicting the aging effects in a TiO₂—TiN/S battery with a Super P coated separator according to certain embodiments of the present disclosure.

### DETAILED DESCRIPTION

The disclosure will be more fully described below with reference to the accompanying drawings. However, the present disclosure may be embodied in a number of different forms and should not be construed as being limited to the embodiments described herein.

### Definitions

Throughout the present disclosure, unless the context requires otherwise, the word “comprise” or variations such as “comprises” or “comprising”, will be understood to imply the inclusion of a stated integer or group of integers but not the exclusion of any other integer or group of integers. It is also noted that in this disclosure and particularly in the claims and/or paragraphs, terms such as “comprises”, “comprised”, “comprising” and the like can have the meaning attributed to it in U.S. patent law; e.g., they can mean “includes”, “included”, “including”, and the like; and that terms such as “consisting essentially of” and “consists essentially of” have the meaning ascribed to them in U.S. patent law, e.g., they allow for elements not explicitly recited, but exclude elements that are found in the prior art or that affect a basic or novel characteristic of the present invention.

Furthermore, throughout the present disclosure and claims, unless the context requires otherwise, the word “include” or variations such as “includes” or “including”, will be understood to imply the inclusion of a stated integer or group of integers, but not the exclusion of any other integer or group of integers.

The use of the singular herein includes the plural (and vice versa) unless specifically stated otherwise. In addition, where the use of the term “about” is before a quantitative value, the present teachings also include the specific quantitative value itself, unless specifically stated otherwise. As used herein, the term “about” refers to a ±10%, ±7%, ±5%, ±3%, ±1%, or ±0% variation from the nominal value unless otherwise indicated or inferred.

The terms “weight percent,” “wt-%,” “percent by weight,” “% by weight,” and variations thereof, as used herein, refer to the concentration of a substance as the weight of that substance divided by the total weight of the composition and multiplied by 100. It is understood that, as used here, “percent,” “%,” and the like are intended to be synonymous with “weight percent,” “wt-%,” etc.

The present disclosure provides a process for producing a TiO₂—TiN composite, which employs a mild liquid-phase oxidation route and enables a controlled oxidation process of TiN to TiO₂, forming an intimately integrated TiO₂—TiN heterostructure. These mild and scalable conditions in the process are crucial for achieving a uniform composite structure with a high surface area and desirable pore architecture. The process ensures the coexistence of TiN and TiO₂ within each particle of the composite, which is vital for combining high conductivity with strong polysulfide adsorption, a balance that is difficult to attain through conventional thermal oxidation methods.

Provided herein is a process for producing a TiO₂—TiN composite, wherein the process comprises:
combining an acid oxidant and an alcohol thereby forming an oxidant mixture; and
combining titanium nitride and the oxidant mixture thereby forming a titanium nitride oxidant mixture; and heating the titanium nitride oxidant mixture at a temperature of 40° C.-80° C. thereby forming the titanium nitride-oxide composite,
wherein the acid oxidant comprises one or more of nitric acid, hydrogen peroxide, K₂Cr₂O₇ and KMnO₄.

In certain embodiments, the alcohol is a C₁-C₁₂alkyl alcohol, C₁-C₁₀ alkyl alcohol, C₁-C₈ alkyl alcohol, C₁-C₆ alkyl alcohol, C₁-C₄ alkyl alcohol, C₁-C₂ alkyl alcohol, or a mixture thereof.

In certain embodiments, the alkyl alcohol comprises methanol, ethanol, propanol, isopropanol, butanol, isobutanol, pentanol, isoamylol, hexanol, or a mixture thereof.

In certain embodiments, the acid oxidant and the alkyl alcohol are combined in a volume ratio ranging from 1:2 to 1:9. In certain embodiments, the acid oxidant and the C₁-C₆ alkyl alcohol are combined in a volume ratio of 1:2, 1:3, 1:4, 1:5, 1:6, 1:7, 1:8, 1:9, or any value ranges therebetween.

In certain embodiments, the ratio of the titanium nitride by weight to the oxidant mixture by volume is in the range of 100 ml to 200 ml per gram of titanium nitride.

In certain embodiments, the oxidation reaction is performed at a temperature of 40° C., 45° C., 50° C., 55° C., 60° C., 65° C., 70° C., 75° C., 80° C., or any value ranges therebetween.

In certain embodiments, the oxidation reaction is performed with stirring. For example, the stirring can generally be performed via magnetic stirring, a stirring paddle, gas stirring, ultrasonic stirring or any other stirring manner.

In certain embodiments, the oxidation reaction is performed for a time period of 8-16 hours. In certain embodiments, the oxidation reaction is performed for a time period of 8 hours, 9 hours, 10 hours, 11 hours, 12 hours, 13 hours, 14 hours, 15 hours, 16 hours, or any value ranges therebetween.

After completion of the oxidation reaction, the resulting reaction mixture can optionally be filtered and washed with distilled water and ethanol, to produce the final product of TiO₂—TiN composite.

In certain embodiments, the process for producing the TiO₂—TiN composite comprises:
combining nitric acid and ethanol in a ratio ranging from 1:2 to 1:9 by volume, thereby forming an oxidant mixture; and
combining titanium nitride and the oxidant mixture thereby forming a titanium nitride oxidant mixture; and heating the titanium nitride oxidant mixture at a temperature of about 60° C. thereby forming the titanium nitride-oxide composite.

The present disclosure provides a titanium nitride-oxide (TiO₂—TiN) composite, which can be produced by the process as disclosed herein. The TiO₂—TiN composite provided herein has a well-defined TiO₂—TiN heterostructure and good structural consistency among different composite particles. The TiO₂—TiN composite can achieve a high BET surface area up to 155.27 m² g⁻¹, and has a hierarchical pore structure with an average pore size of 15.2 nm, comprising both mesopores (2-10 nm) and micropores (0.7-1.5 nm), which are particularly effective for adsorbing lithium polysulfides and accommodating volume changes during cycling.

In certain embodiments, provided herein is a TiO₂—TiN composite, comprising a plurality of TiO₂—TiN particles, wherein each of the TiO₂—TiN particles is composed of a TiO₂ phase and a TiN phase with a TiO₂—TiN heterogeneous interface therebetween.

In certain embodiments, the TiO₂ phase is present in a proportion of 10-90% by weight in the TiO₂—TiN composite. In certain embodiments, the TiO₂ phase is present in a proportion of 10%, 20%, 30%, 40%, 50%, 60%, 70%, 80% or 90% by weight in the TiO₂—TiN composite, or any value ranges therebetween.

In certain embodiments, the TiO₂—TiN composite has a hierarchical pore structure. In particular, the composite provided herein contains pores of multiple size scales arranged in an organized manner, typically spanning from mesopores (2-10 nm) and micropores (0.7-1.5 nm). This multi-level porosity enhances material performance by combining the advantages of different pore sizes, leading to improved properties such as high surface area and efficient transport. The TiO₂—TiN composite with a hierarchical pore structure is particularly effective for adsorbing lithium polysulfides and accommodating volume changes during cycling.

In certain embodiments, the TiO₂—TiN composite comprises the TiN phase as a core that is enveloped by the TiO₂ phase as a shell. In certain embodiments, the TiO₂ shell may fully envelop the TiN core, or may envelop a portion of the surface of TiN core.

In certain embodiments, the TiO₂—TiN composite has a BET specific surface area in the range of 100-160 m²/g. In certain embodiments, the TiO₂—TiN composite has a BET specific surface area of 100 m²/g, 105 m²/g, 110 m²/g, 115 m²/g, 120 m²/g, 125 m²/g, 130 m²/g, 135 m²/g, 140 m²/g, 145 m²/g, 150 m²/g, 155 m²/g, 160 m²/g, or any value ranges therebetween.

The present disclosure further provides a lithium-sulfur (Li—S) battery comprising a cathode electrode comprising the TiO₂—TiN composite described herein. Advantageously, the Li—S battery provided herein can achieve improved cycle stability and coulombic efficiency.

### EXAMPLES

Embodiments of the present disclosure are further defined in the following non-limiting Examples. It should be understood that these Examples, while indicating certain embodiments of the invention, are given by way of illustration only. From the above discussion and these Examples, one skilled in the art can ascertain the essential characteristics of this invention, and without departing from the spirit and scope thereof, can make various changes and modifications of the embodiments of the invention to adapt it to various usages and conditions. Thus, various modifications of the embodiments of the invention, in addition to those shown and described herein, will be apparent to those skilled in the art from the foregoing description. Such modifications are also intended to fall within the scope of the claims.

The present disclosure provides a process for synthesizing a TiO₂—TiN composite through a single-step liquid-phase reaction conducted at mild temperatures, significantly streamlining the production process for large-scale applications. The synthesis method offers a substantial improvement over traditional techniques that require higher temperatures and multiple steps, thereby reducing both the environmental impact and production costs.

Preparation Examples 1-3 illustrate the synthesis process of the titanium nitride-oxide (TiO₂—TiN) composite via a liquid-phase reaction.

### Preparation Example 1

An oxidation mixture of nitric acid (30 ml, 68-69 wt. % nitric acid) and ethanol (120 ml, absolute ethanol) in a ratio of about 1:6 by volume was initially prepared. Into this mixture, approximately 1 gram of titanium nitride (TiN) was introduced. The mixture was then magnetically stirred for 10-12 hours at a temperature of 60° C. After completion of the reaction, the material was filtered and thoroughly washed with distilled water and ethanol. The washed material was subsequently dried in an oven.

### Preparation Example 2

An oxidation mixture of nitric acid and ethanol in a ratio ranging from 1:2 by volume was initially prepared. Into this mixture, approximately 1 gram of titanium nitride (TiN) was introduced. The mixture was then magnetically stirred for 14-16 hours at a temperature of 55° C. After completion of the reaction, the material was filtered and thoroughly washed with distilled water and ethanol. The washed material was subsequently dried in an oven.

### Preparation Example 3

An oxidation mixture of nitric acid and ethanol in a ratio ranging from 1:9 by volume was initially prepared. Into this mixture, approximately 1 gram of titanium nitride (TiN) was introduced. The mixture was then magnetically stirred for 10-12 hours at a temperature of 80° C. After completion of the reaction, the material was filtered and thoroughly washed with distilled water and ethanol. The washed material was subsequently dried in an oven.

### Structural Characterization of the TiO₂—TiN Composite

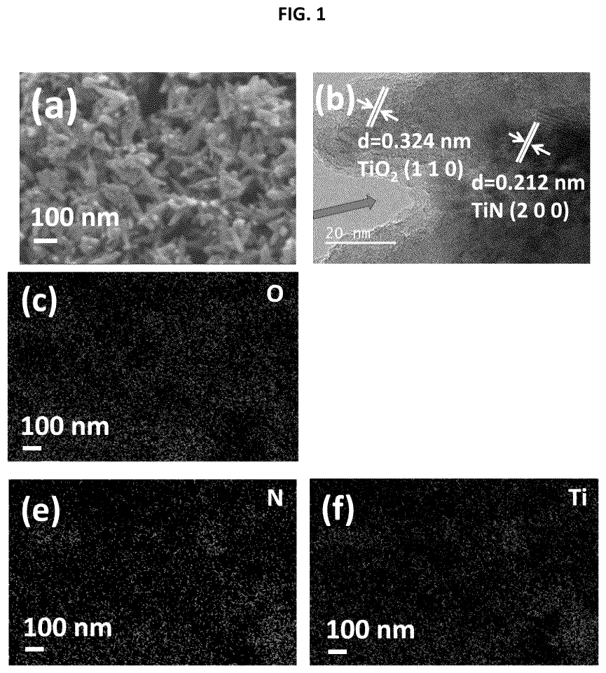

FIG. 1 (a) shows scanning electron microscopy (SEM) images demonstrating the unique structural features of the TiO₂—TiN composite prepared in Preparation Example 1. FIG. 1(a) shows a sponge-like structure composed of leaf-like particles, indicative of the complex morphology of the composite. Transmission electron microscopy (TEM) in FIG. 1(b) further elucidates the dual-layered structure of the composite's surface, showing distinct lattice fringes; the outer shell corresponding to the (110) plane of rutile TiO₂ and the inner core to the (200) plane of TiN, with a clear 20 nm pore diameter visible. Elemental mappings through Energy-Dispersive X-ray spectroscopy (EDX) in FIGS. 1(c), (e) and (f) confirm the presence of Titanium (Ti), Nitrogen (N), and Oxygen (O) as the primary constituents of the composite, supporting the composite's defined chemical structure and enhancing its functional properties.

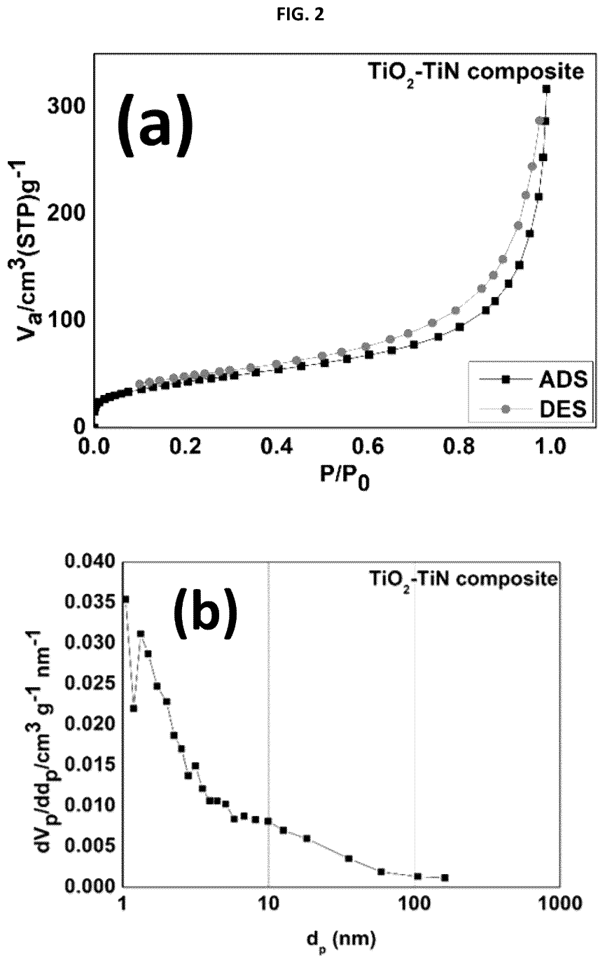

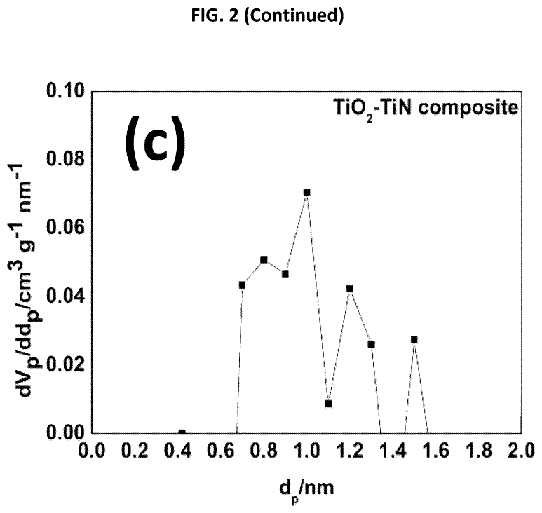

The BET analysis was conducted to assess the surface area and porosity of the TiO2-TiN composite. The results demonstrated that the composite exhibits a high surface area, which is crucial for its application in lithium-sulfur batteries due to the increased adsorption sites for polysulfides. FIG. 2 visually presents these findings, showcasing three distinct plots: a) the adsorption-desorption isotherm, b) the BJH plot, and c) the MP plot. The nitrogen adsorption-desorption isotherms indicated a type IV curve with a distinct hysteresis loop, characteristic of mesoporous materials. This mesoporosity is essential for facilitating electrolyte access and enhancing ion transport within the battery.

The specific surface area measured for the composite prepared in Preparation Example 1 was 155.27 m²/g, and the total pore volume was recorded at 0.87 cm³/g. These properties are indicative of the composite's ability to provide substantial active sites for chemical reactions and storage within the battery structure. Additionally, the pore size distribution confirmed the presence of mesopores, which are optimally sized to accommodate the kinetics of lithium-sulfur interactions, thus enhancing the battery's performance and longevity. This TiO2-TiN composite is suitable for high-performance energy storage applications and has enhanced structural characteristics that contribute to its efficacy and efficiency.

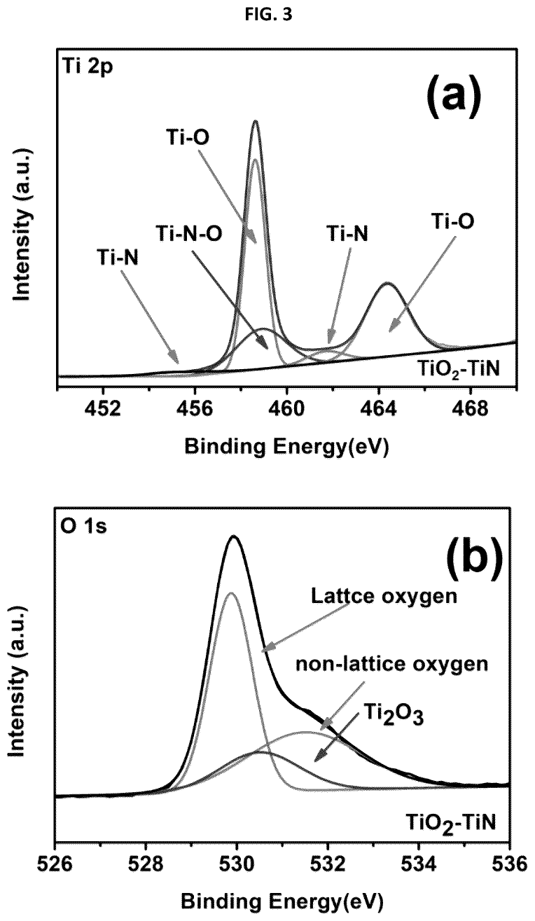

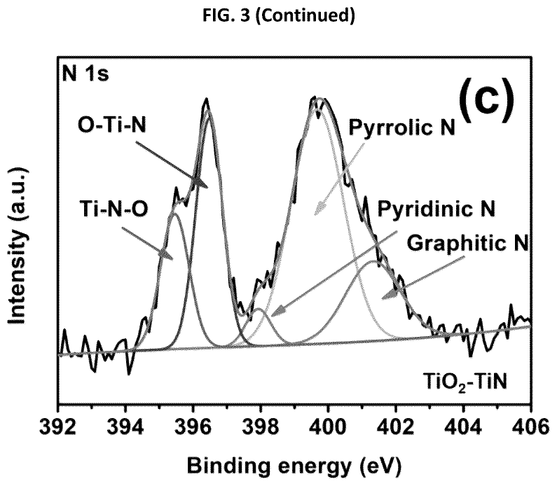

FIG. 3 shows the XPS spectrum of TiO₂—TiN composite prepared in Example 1. FIG. 3(a) reveals the presence of a Ti—N—O peak, indicating that the material is a composite of TiN and TiO2 rather than a mere mixture. In FIG. 3(b), the O 1s XPS spectrum for the TiO₂—TiN composite is fitted with peaks at binding energies of 529.9 eV, 530.3 eV, and 531.3 eV, representing lattice oxygen, Ti₂O₃, and non-lattice oxygen respectively. The emergence of Ti₂O₃ and non-lattice oxygen peaks suggest oxygen vacancies within the lattice. The N is spectrum of TiO₂—TiN, illustrated in FIG. 3(c), detects five nitrogen peaks: the Ti—N—O bond at 395.6 eV, the O—Ti—N bond at 396.4 eV, pyridinic N at 397.9 eV, pyrrolic N at 399.7 eV, and graphitic N at 401.5 eV.

### Cycle Performance of the Lithium-Sulfur Battery

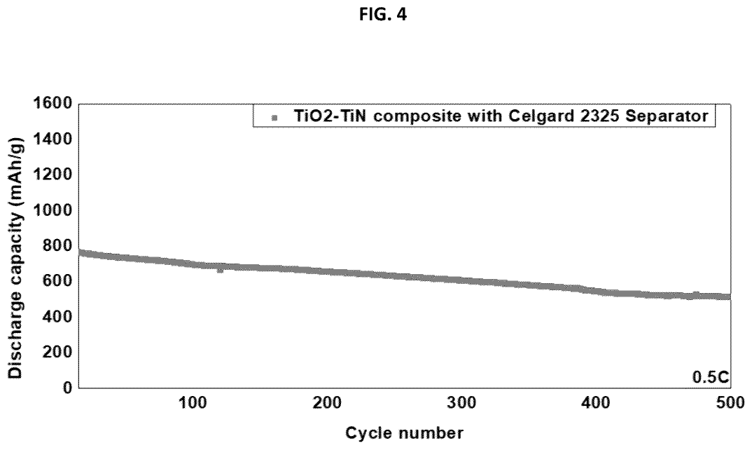

Charge-discharge performance analysis of the lithium-sulfur battery incorporating the TiO₂—TiN composite as a cathode material demonstrated enhanced battery capabilities. As shown in FIG. 4, the initial discharge capacity was recorded over 700 mAh/g, which effectively maintained a capacity of over 500 mAh/g after 500 cycles at a 0.5C rate, showing a low decay rate of 0.06-0.1% per cycle.

This performance indicates the composite's strong impact on improving cycle stability and efficiency of the lithium-sulfur battery. The galvanostatic charge-discharge profiles consistently displayed stable voltage plateaus, underscoring the efficient utilization of the active material and effective suppression of the polysulfide shuttle effect. The capacity retention and low decay rate highlight the composite's ability to enhance the longevity and performance of Li—S batteries, confirming its potential for next-generation energy storage solutions.

The present disclosure further provides an aging-forecasting method for a battery, such as a lithium-sulfur batter, including the deployment of a LSTM network to establish a predictive model based on deep learning techniques. The aging-forecasting method provided by the present disclosure can be used for forecasting the aging effects on batteries, providing accurate predictions up to 100 cycles in advance, significantly enhancing the efficiency of battery testing procedures and quality control measures. Such advancements are crucial for improving the commercial viability and operational efficiency of Li—S batteries.

LSTMs achieve remembering long-term dependencies by incorporating memory cells and gating mechanisms that regulate the flow of information, as these gates—input, forget, and output gates—allow the network to retain or discard information as needed. This capability is particularly beneficial in time-series prediction, where understanding the relationship between distant data points is essential. Batteries undergo complex chemical processes and transitions over numerous charge-discharge cycles, and the ability to predict future performance based on past cycles is critical. By analyzing patterns and trends in the data, LSTMs help in forecasting the lifespan and performance of batteries, thereby enhancing the efficiency of battery testing and evaluation processes.

In certain embodiments, the present application provides a trained LSTM network to establish a predictive model. As predicting curves that exhibit sharp kinks poses unique challenges, LSTM network is applied in the present disclosure. LSTM has the ability to model complex, non-linear relationships, capture the intricate dynamics of data, handle varying time intervals in data, for ultimately improving prediction accuracy. Furthermore, the architecture of LSTMs includes gating mechanisms that help prevent overfitting.

The complexity of relationships in data can be better captured by LSTMs, while LSTMs effectively handle non-linear relationships, especially in time-series data. Meanwhile, LSTMs have built-in gating mechanisms that help prevent overfitting and retain relevant information over long sequences and can perform effectively with smaller datasets, making them suitable for applications with limited data. Finally, LSTMs are adept at filtering out noise and focusing on relevant features, which is crucial when dealing with volatile data.

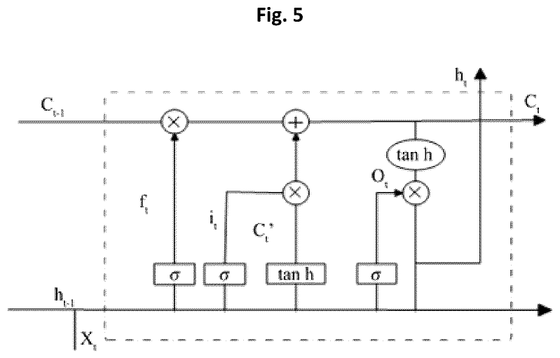

The LSTM network has three gates: input gate, output gate, and forget gate. The module diagram is shown in FIG. 5. Rectangles represent neural network layers, and circles represent point-by-point operations. The control gate is mainly composed of a sigmoid function and a point multiplication operation, which can determine how much information can be transmitted. Adding storage units to the memory gate to store historical information can effectively solve the gradient vanishing problem in the neural network and can further explore the laws existing in the time series.

In certain embodiment, the LSTM network was utilized to predict the aging effects in a battery, such as the TiO2-TiN/S battery with a Super P coated separator. The processor implemented method for predicting aging effects in the battery is provided as follows.
S1, Capturing the data.

In S1, two-column data are received, including voltage and time during multiple charge, that is discharge curves. The parameters were obtained from the experiment. When getting the data, some data from battery cycles are removed so as to avoid the potential error, for example the first 24 battery cycles as the data in these cycles are warm-up data. The other data in the experimental data beyond the warm-up cycles is generally consistent.
S2, Inputting the data of voltage and time curve into a trained LSTM network.
S3, Outputting the predicted data of voltage and time curve.

The trained LSTM network is established and trained as follows.

The LSTM operation allows a network to learn long-term dependencies between time steps in time series and sequence data, applying the deep learning LSTM operation to dlarray data. When applying an LSTM operation within a dlnetwork object, use LSTM Layer. Further, sigmoid activation function and the tanh activation function are used for training the LSTM model. The inputs to the LSTM network are the experimental data of the selected input sample length. For example, the input sample length of the experimental data is 2000. In certain embodiment, for training the LSTM network, the number of iterations is 50 epochs, the learning rate is 0.0001.

When establishing a LSTM network, the following is applied.

Y=lstm(X,H0,C0,weights,recurrent Weights,bias)

wherein X is the input, H0 refers to the initial hidden state, C0 refers to the initial cell state. The input X is a formatted dlarray including the voltage and the time measured in the experiment. Input data, specified as a formatted dlarray, an unformatted dlarray, or a numeric array. When X is not a formatted dlarray, the dimension label format is specified using the DataFormat option. If X is a numeric array, at least one of H0, C0, weights, recurrentWeights, or bias must be a dlarray. Preferably, X contains a sequence dimension labeled “V” (Voltage) and “T” (time). If X has any spatial dimensions labeled “S”, they are flattened into the “C” channel dimension. If X does not have a channel dimension, then one is added. If X has any unspecified dimensions labeled “U”, they must be singleton. The output Y is a formatted dlarray with the same dimension format as X, except for any “S” dimensions.

In the LSTM network in the curtain embodiment, the cell and hidden states are updated using the hyperbolic tangent function (tanh) as the state activation function. In certain embodiment, the LSTM network uses the sigmoid function as the gate activation function.

Further, [Y,hiddenState,cellState]=lstm(X, H0, C0, weights, recurrentWeights, bias) also returns the hidden state and cell state after the LSTM operation.

In certain embodiment, performing an LSTM operation using three hidden units. In certain embodiment, the step includes create the initial hidden and cell states with three hidden units, in which the same initial hidden state and cell state are used for all observations. numHiddenUnits=3; H0=zeros(numHiddenUnits,1); C0=zeros(numHiddenUnits,1).

In certain embodiment, the step includes creating the learnable parameters for the LSTM operation. In this process, weights=dlarray(randn(4*numHiddenUnits,numFeatures), “CU”); recurrentWeights=dlarray(randn(4*numHiddenUnits,numHiddenUnits), “CU”); bias=dlarray(randn(4*numHiddenUnits,1), “C”).

The LSTM output is returned as a dlarray. The output Y has the same underlying data type as the input X. Hidden state vector for each observation, returned as a dlarray or a numeric array with the same data type as H0. If the input H0 is a formatted dlarray, then the output hiddenState is a formatted dlarray with the format “CB”. Cell state vector for each observation, returned as a dlarray or a numeric array. cellState is returned with the same data type as C0.

If the input C0 is a formatted dlarray, the output cell State is returned as a formatted dlarray with the format ‘CB’.

The data format is a string of characters, where each character describes the type of the corresponding data dimension. Generally, the characters are: “S”—Spatial; “C”—Channel; “B”—Batch; “T”—Time; “U”—Unspecified.

In certain embodiment, the LSTM network can comprise a sequence input layer for handling the time-series data, an LSTM layer with 200 hidden units that process these sequences, and a fully connected layer that outputs the final predictions. In certain embodiment, the weights of the features in the above formula are adjusted automatically during the training process using the Adam optimization algorithm, with parameters such as the initial learning rate and learning rate schedule specified in the training options function influencing how the weights are updated. The loss function selected for this configuration is typically RMSE, which is suitable for regression tasks as it minimizes the difference between predicted and actual values.

In certain embodiment, LSTM network is established and employed to predict aging effects in batteries made with a titanium nitride-oxide (TiO₂—TiN) composite. The LSTM network has been trained to minimize the RMSE, which stabilized after approximately 500 epochs. Predictions for up to 200 cycles highlighted challenges in capturing complex chemical transitions, particularly the polysulfide phase changes. Extensive parameter optimization for the LSTM has been conducted to enhance the model's accuracy. Meanwhile, adjustments to the learning rate and gradient thresholds have been made to address discrepancies in charge and discharge predictions, notably improving RMSE values between cycle 150 and 200.

More specifically, the training options for the LSTM network are configured using the trainingOptions function with the ‘adam’ optimization algorithm. The maximum number of epochs is set to 500, allowing for sufficient training iterations. A gradient threshold of 0.1 is established to prevent excessively large gradients, which can destabilize the training process. The initial learning rate is specified as 0.003, and the learning rate schedule is set to ‘piecewise’, enabling adjustments during training. The drop factor of learning rate is 0.62, helping to fine-tune the learning as the training progresses. The verbosity level is set to 0, which suppresses detailed output during training, while the ‘Plots’ option is enabled to visualize the training progress. This configuration aims to optimize the training process for improved model performance. The training data is collected from 25th to 100th cycle. The comparison between the prediction by LSTM network and experimental charge and discharge curves which shows a comparison at the 200th cycle with RMSE=0.005.

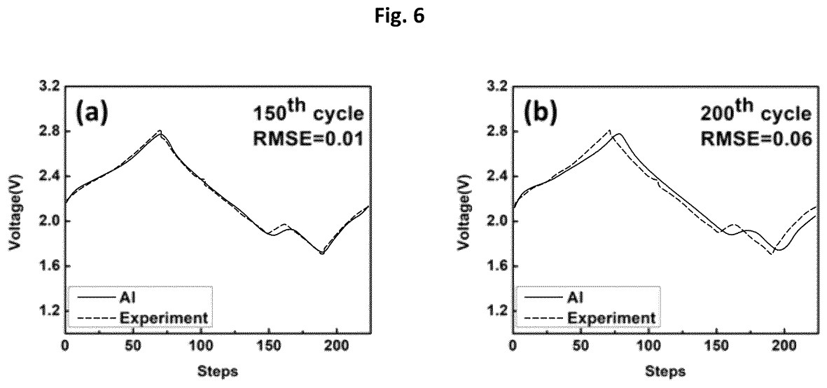

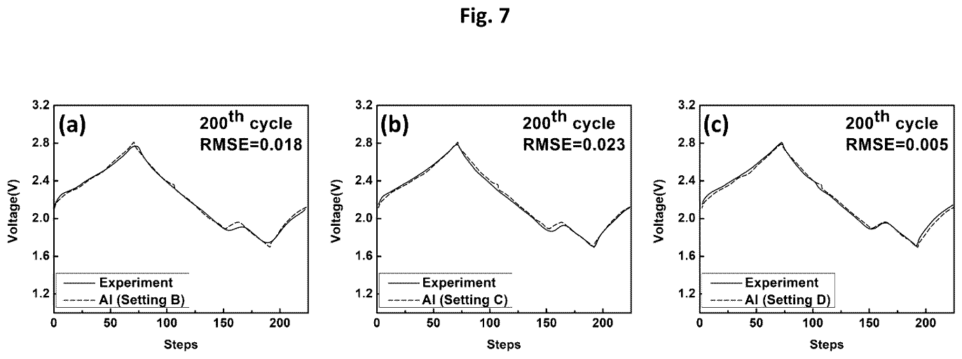

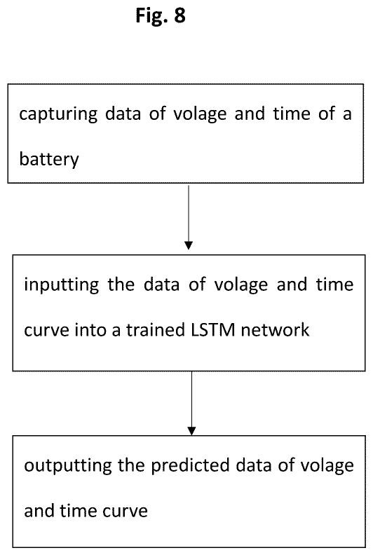

In certain embodiment, to enhance the predictive accuracy of the LSTM network, an extensive optimization of its parameters was undertaken, the details of which are summarized in Table 1. That is, Table 1 lists the selected LSTM parameters for the training data this duration of 500th epoch was selected for the LSTM training, as documented in Table 1. FIG. 6 (a-b) shows the predicted charge and discharge curves for future cycles by the LSTM, where one step equates to approximately 30 seconds. FIG. 7 (a-c) shows the diagram of the LSTM results with the selected training parameters, wherein (a) shows the estimated voltage changes obtained using setting B in Table 1 by the LSTM model and measured via experiment during 200 cycle steps when the RMSE is 0.018, (b) shows the estimated voltage changes obtained using setting C in Table 1 by the LSTM model and measured via experiment during 200 cycle steps when the RMSE is 0.023, (c) shows the estimated voltage changes obtained using setting D in Table 1 by the LSTM model and measured via experiment during 200 cycle steps when the RMSE is 0.005. As shown in FIG. 7 (a-c), the final optimized LSTM model demonstrated a significantly closer alignment with experimental data, showcasing the effectiveness of these adjustments. The optimized LSTM parameters crucially improved the network's ability to predict detailed battery behaviours, ensuring reliable forecasts and enhancing the model's application in battery technology development.

TABLE 1
The selected LSTM parameters for the training data.

| | Setting A | Setting B | Setting C | Setting D |
|---|---|---|---|---|
| Gradient threshold | 0.5 | 0.1 | 0.1 | 0.1 |
| Initial learning rate | 0.001 | 0.001 | 0.003 | 0.003 |
| Learning rate (drop | 0.2 | 0.2 | 0.2 | 0.62 |
| factor) | | | | |

In the above embodiments, RMSE is analyzed as a function of epoch number, and the plateau in RMSE reduction reached at the 500th epoch, adjusting the drop period to 120 epochs. By manipulating the selected parameters of the LSTM model, accurate forecasting of battery performance at the 200th cycle was not only achieved, but it was also discovered that these parameters played a critical role in minimizing the forecasting error for battery curves up to the 200th cycle. The comprehensive optimization of the LSTM parameters played a pivotal role in enhancing the AI's predictive accuracy for the battery's charging and discharging cycles. The objective of testing different values for each parameter was to assess their impact on predictive accuracy and identify the most effective settings for the LSTM model. Notably, adjusting the gradient threshold proved instrumental in maintaining high accuracy in predictions, except in discontinuous regions. The optimized predictions, as shown in FIG. 7 (a-c), demonstrated a closer alignment with the experimental data, highlighting the success of these parameter adjustments in improving the LSTM model's forecasting capabilities.

The ne-tuning aimed to address this localized inaccuracy, and the resulting improvements illustrate how these adjustments enhanced the model's precision in this critical step range, reducing the previously observed errors and thereby improving the overall forecasting reliability of the LSTM network. By manipulating the selected parameters of the LSTM model, accurate forecasting of battery performance at the 200th cycle was not only achieved, but it was also discovered that these parameters played a critical role in minimizing the forecasting error for battery curves up to the 200th cycle. The comprehensive optimization of the LSTM parameters played a pivotal role in enhancing the AI's predictive accuracy for the battery's charging and discharging cycles. By modulating the initial learning rate, the model achieved faster convergence and effectively circumvented potential stalls at local optima, thereby returning its predictive accuracy. Additionally, setting an appropriate gradient threshold was instrumental in preventing issues, such as exploding or vanishing gradients, contributing to stable model training and improved prediction result. Furthermore, the careful calibration of the learning rate's drop factor facilitated adjustments in the model's parameter updates as it neared convergence. This approach prevented oscillations around the optimal solution, ensuring consistent and precise predictions throughout the training process, which is crucial for accurately forecasting battery behavior.

The present disclosure is further illustrated by the following embodiments.
1. A process for producing a TiO₂—TiN composite, wherein the process comprises:
combining an acid oxidant and an alcohol thereby forming an oxidant mixture; and
combining titanium nitride and the oxidant mixture thereby forming a titanium nitride oxidant mixture; and heating the titanium nitride oxidant mixture at a temperature of 40° C.-80° C. thereby forming the titanium nitride-oxide composite,
wherein the acid oxidant comprises one or more of nitric acid, hydrogen peroxide, K₂Cr₂O₇ and KMnO₄.
2. The process for producing the TiO₂—TiN composite of embodiment 1, wherein the alcohol is a C₁-C₁₂ alkyl alcohol, C₁-C₁₀ alkyl alcohol, C₁-C₈ alkyl alcohol, C₁-C₆ alkyl alcohol, C₁-C₄ alkyl alcohol, C₁-C₂ alkyl alcohol, or a mixture thereof.
3. The process for producing the TiO₂—TiN composite of embodiment 1 or 2, wherein the alcohol comprises methanol, ethanol, propanol, isopropanol, butanol, isobutanol, pentanol, isoamylol, hexanol, or a mixture thereof.
4. The process for producing the TiO₂—TiN composite of any one of embodiments 1-3, wherein the acid oxidant and the alkyl alcohol are combined in a volume ratio ranging from 1:2 to 1:9.
5. The process for producing the TiO₂—TiN composite of any one of embodiments 1-4, wherein the ratio of the titanium nitride by weight to the oxidant mixture by volume is in the range of 100 ml to 200 ml per gram of titanium nitride.
6. The process for producing the TiO₂—TiN composite of any one of embodiments 1-5, wherein the oxidation reaction is performed at a temperature ranging from 50-70° C.
7. The process for producing the TiO₂—TiN composite of any one of embodiments 1-6, wherein the oxidation reaction is performed for a time period of 8-16 hours.
8. The process for producing the TiO₂—TiN composite of any one of embodiments 1-7, wherein the process for producing the TiO₂—TiN composite comprises:
combining nitric acid and ethanol in a ratio ranging from 1:2 to 1:9 by volume, thereby forming an oxidant mixture; and
combining titanium nitride and the oxidant mixture thereby forming a titanium nitride oxidant mixture; and heating the titanium nitride oxidant mixture at a temperature of about 60° C. thereby forming the titanium nitride-oxide composite.
9. A TiO₂—TiN composite, comprising a plurality of TiO₂—TiN particles, wherein each of the TiO₂—TiN particles is composed of a TiO₂ phase and a TiN phase with a TiO₂—TiN heterogeneous interface therebetween.
10. The TiO₂—TiN composite of embodiment 9, wherein the TiO₂ phase is present in a proportion of 10-90% by weight in the TiO₂—TiN composite.
11. The TiO₂—TiN composite of embodiment 9 or 10, wherein the TiO₂—TiN composite has a hierarchical pore structure.
12. The TiO₂—TiN composite of any one of embodiments 9-11, wherein the TiO₂—TiN composite comprises the TiN phase as a core, which is enveloped by the TiO₂ phase as a shell.
13. The TiO₂—TiN composite of any one of embodiments 9-12, wherein the TiO₂—TiN composite has a BET specific surface area in the range of 100-160 m²/g.
14. A lithium-sulfur (Li—S) battery comprising a cathode electrode comprising the TiO₂—TiN composite according to any one of embodiments 9-13, or produced by the process according to any one of embodiments 1-8.

The disclosed experimental data was designed to establish the feasibility and reproducibility of the claimed process under representative conditions. The chosen materials and process parameters reflect the desired outcomes and are aligned with standard practices in the field. The focus of the current disclosure was to demonstrate the viability of the process under the specific conditions described. While the experimental data provided focuses on specific conditions, the process is not intended to be limited to these embodiments. The methodology described herein is adaptable to a range of conditions, and variations in electrolytes, precipitants, and surfactants could be explored to optimize the process for specific applications. The selection of the described parameters was based on their practical relevance and alignment with the objectives of this invention.

The embodiments or elements showcased within this disclosure, including the specific illustrations and materials utilized in examples, are intended to be illustrative, not restrictive. They allow for a wide range of alterations, adjustments, or adaptations that align with the fundamental concept of the present disclosure. It's important to clarify that all depicted diagrams are solely for illustrative purposes; they are neither to scale nor are they precise reproductions of actual devices.

Wherever not already described explicitly, individual embodiments, or their individual aspects and features, described in relation to the drawings can be combined or exchanged with one another without limiting or widening the scope of the described disclosure, whenever such a combination or exchange is meaningful and in the sense of this disclosure. Advantages which are described with respect to a particular embodiment of present disclosure or with respect to a particular figure are, wherever applicable, also advantages of other embodiments of the present disclosure.

What is claimed is:

1. A processor implemented method of predicting aging effects in a battery, the method comprising:
1) capturing data of voltage and time of the battery;
2) inputting the data of voltage and time curve into a trained long short-time memory (LSTM) network;
3) outputting the predicted data of voltage and time curve;
wherein the trained LSTM network is configured to be trained by the following steps:
selecting an input data sample;
defining an initial hidden state, an initial cell state, bias, weight, current weight;
setting an epoch, an initial learning rate, a gradient threshold, and a drop factor; and
training the LSTM network as per the set parameters.

2. The processor implemented method according to claim 1, wherein the loss function for training the LSTM network is a root-mean-square error (RMSE).

3. The processor implemented method according to claim 1, wherein the number of epochs is set to be equal to or less than 500, the gradient threshold is set to be equal to 0.1, and the initial learning rate is specified as 0.003.

4. The processor implemented method according to claim 1, wherein the drop factor is set to be equal to 0.2 or 0.62.

5. The processor implemented method according to claim 2, wherein the number of epochs is set to be equal to 200 with RMSE=0.005.

6. A system for predicting aging effects in a battery, the system comprising a memory, a processor, and computer program instructions stored in the memory and capable of being run by the processor, and when the computer program is run by the processor, the method of claim 1 is implemented.

7. A system for predicting aging effects in a battery, the system comprising a memory, a processor, and computer program instructions stored in the memory and capable of being run by the processor, and when the computer program is run by the processor, the method of claim 2 is implemented.

8. A system for predicting aging effects in a battery, the system comprising a memory, a processor, and computer program instructions stored in the memory and capable of being run by the processor, and when the computer program is run by the processor, the method of claim 3 is implemented.

9. A system for predicting aging effects in a battery, the system comprising a memory, a processor, and computer program instructions stored in the memory and capable of being run by the processor, and when the computer program is run by the processor, the method of claim 4 is implemented.

10. A system for predicting aging effects in a battery, the system comprising a memory, a processor, and computer program instructions stored in the memory and capable of being run by the processor, and when the computer program is run by the processor, the method of claim 5 is implemented.
